(19) United States
(12) Patent Application Publication
(10) Pub. No.: US 2009/0044848 A1
(43) Pub. Date: Feb. 19, 2009

(54) Nanostructured Material-Based Thermoelectric Generators

(75) Inventors: David S. Lashmore, Lebanon, NH (US); Meghann White, Manchester, NH (US); Brian White, Manchester, NH (US); David Degtiarov, Newton, MA (US); Jennifer Mann, Chichester, NH (US)

Correspondence Address: GREENBERG TRAURIG, LLP, ONE INTERNATIONAL PLACE, 20th FL, ATTN: PATENT ADMINISTRATOR, BOSTON, MA, 02110, US

(73) Assignee: Nanocomp Technologies, Inc.

(21) Appl. No.: 12/191,765

(22) Filed: Aug. 14, 2008

Related U.S. Application Data
(60) Provisional application No. 60/964,678, filed on Aug. 14, 2007.
(60) Provisional application No. 60/987,304, filed on Nov. 12, 2007.

(51) Int. Cl. H01L 35/28; H01L 35/34; B60K 16/00

(52) U.S. Cl. 136/201; 136/205; 136/206; 60/641.8; 977/742

(57) ABSTRACT

A thermoelectric device that can exhibit substantially high specific power density is provided. The device includes core having a p-type element made from carbon nanotube and an n-type element. The device also includes a heat plate in and a cool plate, between which the core can be positioned. The design of the thermoelectric device allows the device to operate at substantially high temperature and to generate substantially high power output, despite being light weight. A method for making the thermoelectric device is also provided.

### RELATED U.S. APPLICATIONS

The present invention claims priority to U.S. Provisional Patent Application Nos. 60/964,678, filed Aug. 14, 2007, and 60/987,304, filed Nov. 12, 2007, both of which are hereby incorporated herein by reference.

### TECHNICAL FIELD

The present invention relates to power generators, and more particularly, to electric power generators using thermoelectric effect associated with nanostructured material arrays.

### BACKGROUND ART

Thermal electric generators are usually made from semiconductor “n” and “p” type elements arranged in series “n” to “p”, and can be attached on one side to a hot plate or heat source, and on the other side to a cold plate or heat sink. The efficiency of these generators includes fundamentally the Carnot efficiency and secondarily the device efficiency, with overall energy conversion values of less than about 10% and usually less than about 5%.

These devices typically rely on semiconductor materials having, among other things, a relatively high Seebeck coefficient, S, a change in voltage with temperature, a high electrical conductivity, σ, and a low thermal conductivity, λ.

The figure of merit, therefore, can be expressed as:

ZT=S²*σ*ΔT/λ (1)

so that materials with a high thermal conductivity λ tend to behave poorly as thermoelectric generators, because they can leak away thermal energy that otherwise can contribute to power generation.

It should be noted that the weight of these materials, in many instances, typically does not come into consideration. However, for many practical considerations, weight may be important. For example, Bi₂Te₃, an often used material in the manufacturing of thermoelectric devices because its ZT value is about 1, has a density of about 7.4 g/cc to about 7.7 g/cc. As such, devices made of this high performace material can be relatively heavy.

Moreover, many of the applications for which the use of a thermoelectric generator can be contemplated requires a thermoelectric device that has a substantially high specific power. As an example, for single junction solar cell based arrays, a specific power of from about 25 W/kg to about 100 W/kg needs to be achieved. In addition, for future applications using, for instance, multi-junction GaAs arrays, a specific power of from about 200 W/kg to about 1000 W/kg may be needed.

However, thermoelectric devices or systems that utilize Bi₂Te₃, SiGe alloys, or other similar materials can only generate a specific power at a level of from about 1-5 W/kg. Furthermore, in many of the contemplated applications, the temperatures to which the thermoelectric devices can be exposed can be substantially high. Unfortunately, Bi₂Te₃, SiGe alloys, or other similar materials used in presently available thermoelectric devices or systems tend to melt as the temperature approaches about 400° C.

Accordingly, it would be desirable to provide thermoelectric devices that are efficient, yet lightweight, that can operate at substantially high temperature, and that can generate the necessary voltage to permit useful applications.

### SUMMARY OF THE INVENTION

The present invention provides, in accordance with one embodiment, a thermoelectric device for use in the generation of power, as well as other applications.

In one embodiment, the thermoelectric device includes a first member designed to collect heat from a heat source. The first member can be designed to withstand temperatures ranging from below 0° C. up to about 600° C. and above. The thermoelectric device can also include a second member in spaced relations from the first member for dissipating heat from the first member. The first and second member, in an embodiment, may be made from a thermally conductive material, such a aluminum nitride. The thermoelectric device further includes a core positioned between the first member and a second member for converting heat from the first member to useful energy. In one embodiment, the core includes a nanotube thermal element exhibiting a relatively high Seebeck coefficient that increases with an increase in temperature, and a conductive element exhibiting a relatively high transition temperature. The thermal element, in an embodiment, may have a density range of from about 0.1 g/cc to about 1.0 g/cc, which can result in weight saving over traditional materials used in a thermoelectric device. The thermal element and conductive element may be coupled to one another, so as to allow the core to operate within in a substantially high temperature range, for example up to about 600° C. and above. In addition, the core may be designed to achieve a relatively high specific power up to and exceeding about 3 W/g at a ΔT of about 400° C.

In another embodiment, a method of generating power is provided. The method includes initially providing a thermoelectric device having (i) a first member designed to collect heat from a heat source, (ii) a second member in spaced relations from the first member for dissipating heat from the first member, and (iii) a core positioned between the first member and a second member for converting heat from the first member to useful energy, the core having a nanotube thermal element exhibiting a relatively high Seebeck coefficient that increases with an increase in temperature, and a conductive element exhibiting a relatively high transition temperature, the elements coupled to one another allowing the core to operate in a substantially high temperature range. Next the thermoelectric device can be positioned so as to permit the first member to collect heat from a heat source. Thereafter, the collected heat can be driven across the core to the second member due to a temperature differential between the first member and the second member. Subsequently, during the course of heat transfer, the core is allowed to convert the heat transferred across it into power. In one embodiment, once power has been generated, the power can be directed to another to permit such a device to operate. Alternatively, if the thermoelectric device is coupled to a machine or device capable of generating waste heat, so that the waste heat can act as a heat source to be captured, the device can convert the waste heat to power and redirect the power to the machine for further use. To enhance efficiency and power generated, the number of thermal elements and conductive elements in the core can be increased. In addition, the power generated can be up to and exceeding about 3 W/g at a ΔT of about 400° C.

A method of manufacturing a thermoelectric device is also provided. The method includes initially providing at least one nanotube thermal element exhibiting a relatively high Seebeck coefficient that increases with an increase in temperature. In one embodiment, the nanotube thermal element can be provided with a density range of from about 0.1 g/cc to about 1.0 g/cc. In addition, the nanotube thermal element can be doped with one of a p-type dopant, n-type dopant, or both. Next, the thermal element can be coupled to a corresponding conductive element exhibiting a relatively high transition temperature to provide a core member. In one embodiment, the thermal element and the conductive element can withstand a temperature range of from below 0° C. up to about 600° C. and above. Thereafter, the core member may be positioned between a first member designed to collect heat from a heat source, and a second member in spaced relations from the first member for dissipating heat from the first member. To provide the thermoelectric device with the ability to increase the power generated, in one embodiment, the number of nanotube thermal elements on can be increased.

### BRIEF DESCRIPTION OF DRAWINGS

FIG. 1 illustrates a Chemical Vapor Deposition system for fabricating a continuous sheet of nanotubes, in accordance with one embodiment of the present invention.

FIG. 2 illustrate a illustrate a Chemical Vapor Deposition system for fabricating a yarn made from nanotubes, in accordance with one embodiment of the present invention.

FIG. 3 illustrates the relationship between power conversion efficiency as a function of ZT.

FIG. 4 illustrates the Seebeck coefficient for individual nanotubes as a function of temperature.

FIG. 5 illustrates the Seebeck coefficient as a function of temperature for single-wall nanotube sheets.

FIG. 6 illustrates the power output from a thermoelectric device made with single-wall nanotube sheets as a function of temperature.

FIG. 7 illustrates linear array with copper plated onto single-wall nanotube sheet for use as a component of a thermoelectric device of the present invention.

FIGS. 8A-B illustrates the linear array in FIG. 7 wrapped up to provide a core of a thermoelectric device.

FIG. 9 illustrates a pocket solar collector with a thermoelectric device of the present invention.

FIG. 10 illustrates another solar collector with another configuration of a thermoelectric device, in accordance with an embodiment of the present invention.

FIGS. 11A-D illustrate a multi-element thermoelectric array for use as a thermoelectric device.

FIGS. 12A-B illustrate data from a thermoelectric device having a 5 element array and from thermoelectric device having a 30 element array.

FIGS. 13A-B illustrate a thermoelectric device having an alternating array core for energy harvesting, in accordance with an embodiment of the present invention.

FIG. 14 illustrates a thermoelectric core contained inside the thermoelectric device shown in FIGS. 13A-B.

### DESCRIPTION OF SPECIFIC EMBODIMENTS

Carbon nanotubes, such as those manufactured in accordance with an embodiment of the present invention, can exhibit a significant Seebeck effect. In particular, these carbon nanotubes can exhibit a Seebeck coefficient that may be substantially linear with temperatures, for instance, from ambient to at least about 600° C. Moreover, the Seebeck coefficient for a structure made with substantially aligned carbon nanotubes of the present invention can be measurably higher.

Furthermore, the carbon nanotubes of the present invention can have lower density than traditional materials used in making thermoelectric generators. As such, significant weight saving can be achieved by replacing the relatively heavy traditional materials with the lighter carbon nanotubes of the present invention. Due to their relatively lower density, relatively higher Seebech effect, and relatively lower thermal conductivity, carbon nanotubes can be designed to achieve relatively high specific power.

Thermoelectric devices or generators of the present invention may be manufactured using, in one embodiment, at least one sheet or one yarn made from single, dual, or multiwall carbon nanotubes. In one embodiment, the sheet or yarn may be doped with p-type or n-type dopants, and subsequently coupled to a conductive material, such as copper or nickel. These affixed elements (i.e., doped sheet or yarn, and conductive material) may, thereafter, be arranged or assembled in various configurations to provide the thermoelectric devices or generators of the present invention. It should be appreciated that the flexibility and low density of carbon nanotubes, and thus the sheet or yarn, permit geometries that would not otherwise be possible with traditional semiconductor materials.

### Systems for Fabricating Nanotubes

Nanotubes for use in connection with the present invention may be fabricated using a variety of approaches. Presently, there exist multiple processes and variations thereof for growing nanotubes. These include: (1) Chemical Vapor Deposition (CVD), a common process that can occur at near ambient or at high pressures, and at temperatures above about 400° C., (2) Arc Discharge, a high temperature process that can give rise to tubes having a high degree of perfection, (3) Laser ablation, and (4) HIPCO.

The present invention, in one embodiment, employs a CVD process or similar gas phase pyrolysis procedures known in the industry to generate the appropriate nanostructures, including carbon nanotubes. Growth temperatures for a CVD process can be comparatively low ranging, for instance, from about 400° C. to about 1350° C. Carbon nanotubes, both single wall (SWNT) or multiwall (MWNT), may be grown, in an embodiment of the present invention, by exposing nanoscaled catalyst particles in the presence of reagent carbon-containing gases (i.e., gaseous carbon source). In particular, the nanoscaled catalyst particles may be introduced into the reagent carbon-containing gases, either by addition of existing particles or by in situ synthesis of the particles from a metal-organic precursor, or even non-metallic catalysts. Although both SWNT and MWNT may be grown, in certain instances, SWNT may be selected due to their relatively higher growth rate and tendency to form rope-like structures. These rope-like structures can offer a number of advantages, including handling, lower thermal conductivity which can be a desirable feature for thermoelectric devices, good electronic conductivity, and high strength.

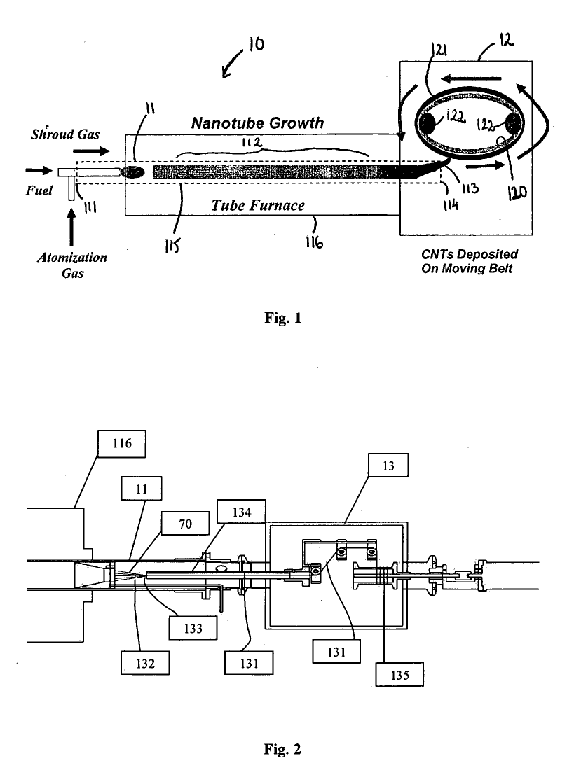

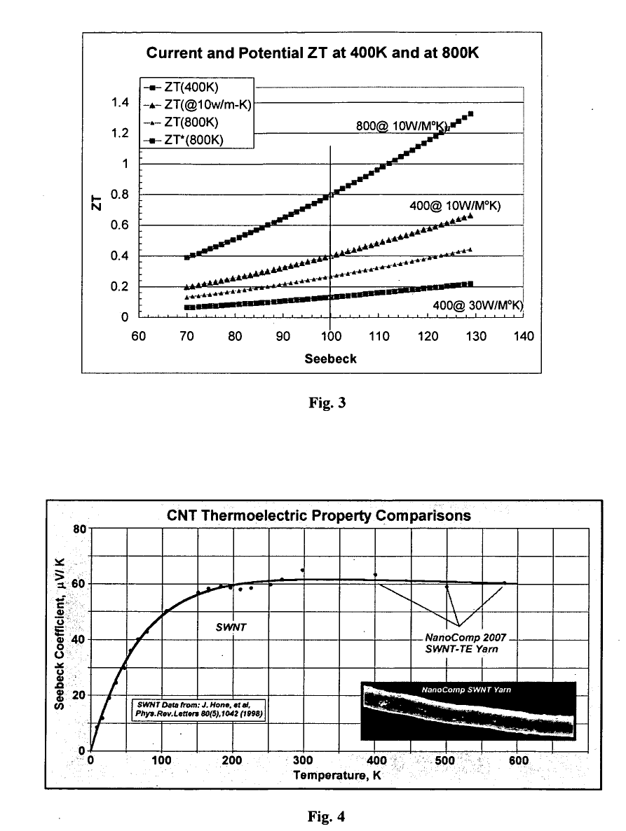

With reference now to FIG. 1, there is illustrated a system 10, similar to that disclosed in U.S. patent application Ser. No. 11/488,387 (incorporated herein by reference), for use in the fabrication of nanotubes. System 10, in an embodiment, may be coupled to a synthesis chamber 11. The synthesis chamber 11, in general, includes an entrance end 111, into which reaction gases (i.e., gaseous carbon source) may be supplied, a hot zone 112, where synthesis of extended length nanotubes 113 may occur, and an exit end 114 from which the products of the reaction, namely the nanotubes and exhaust gases, may exit and be collected. The synthesis chamber 11, in an embodiment, may include a quartz tube 115 extending through a furnace 116. The nanotubes generated by system 10, on the other hand, may be individual single-walled nanotubes, bundles of such nanotubes, and/or intertwined single-walled nanotubes (e.g., ropes of nanotubes).

System 10, in one embodiment of the present invention, may also include a housing 12 designed to be substantially airtight, so as to minimize the release of potentially hazardous airborne particulates from within the synthesis chamber 11 into the environment. The housing 12 may also act to prevent oxygen from entering into the system 10 and reaching the synthesis chamber 11. In particular, the presence of oxygen within the synthesis chamber 11 can affect the integrity and compromise the production of the nanotubes 113.

System 10 may also include a moving belt 120, positioned within housing 12, designed for collecting synthesized nanotubes 113 made from a CVD process within synthesis chamber 11 of system 10. In particular, belt 120 may be used to permit nanotubes collected thereon to subsequently form a substantially continuous extensible structure 121, for instance, a non-woven sheet. Such a non-woven sheet may be generated from compacted, substantially non-aligned, and intermingled nanotubes 113, bundles of nanotubes, or intertwined nanotubes (e.g., ropes of nanotubes), with sufficient structural integrity to be handled as a sheet.

To collect the fabricated nanotubes 113, belt 120 may be positioned adjacent the exit end 114 of the synthesis chamber 11 to permit the nanotubes to be deposited on to belt 120. In one embodiment, belt 120 may be positioned substantially parallel to the flow of gas from the exit end 114, as illustrated in FIG. 2. Alternatively, belt 120 may be positioned substantially perpendicular to the flow of gas from the exit end 114 and may be porous in nature to allow the flow of gas carrying the nanomaterials to pass therethrough. Belt 120 may be designed as a continuous loop, similar to a conventional conveyor belt. To that end, belt 120, in an embodiment, may be looped about opposing rotating elements 122 (e.g., rollers) and may be driven by a mechanical device, such as an electric motor. Alternatively, belt 120 may be a rigid cylinder. In one embodiment, the motor may be controlled through the use of a control system, such as a computer or microprocessor, so that tension and velocity can be optimized.

In an alternate embodiment, as illustrated in FIG. 2, instead of a non-woven sheet, the fabricated single-walled nanotubes 113 may be collected from synthesis chamber 11, and a yarn 131 may thereafter be formed. Specifically, as the nanotubes 113 emerge from the synthesis chamber 11, they may be collected into a bundle 132, fed into intake end 133 of a spindle 134, and subsequently spun or twisted into yarn 131 therewithin. It should be noted that a continual twist to the yarn 131 can build up sufficient angular stress to cause rotation near a point where new nanotubes 113 arrive at the spindle 134 to further the yarn formation process. Moreover, a continual tension may be applied to the yarn 131 or its advancement into collection chamber 13 may be permitted at a controlled rate, so as to allow its uptake circumferentially about a spool 135.

Typically, the formation of the yarn 131 results from a bundling of nanotubes 113 that may subsequently be tightly spun into a twisting yarn. Alternatively, a main twist of the yarn 131 may be anchored at some point within system 10 and the collected nanotubes 113 may be wound on to the twisting yarn 131. Both of these growth modes can be implemented in connection with the present invention.

### Nanotubes

The strength of the individual carbon nanotubes generated in connection with the present invention may be about 30 GPa or more. Strength, as should be noted, is sensitive to defects. However, the elastic modulus of the carbon nanotubes fabricated in the present invention may not be sensitive to defects and can vary from about 1 to about 1.2 TPa. Moreover, the strain to failure of these nanotubes, which generally can be a structure sensitive parameter, may range from a about 10% to a maximum of about 25% in the present invention.

The nanotubes of the present invention can also be provided with relatively small diameter. In an embodiment of the present invention, the nanotubes fabricated in the present invention can be provided with a diameter in a range of from less than 1 nm to about 10 nm.

The carbon nanotubes of the present invention can further demonstrate ballistic conduction as a fundamental means of conductivity. Thus, materials made from nanotubes of the present invention can represent a significant advance over copper and other metallic conducting members under AC current conditions.

Moreover, the carbon nanotubes of the present invention can be provided with a density of from about 0.1 g/cc to about 1.0 g/cc, and more particularly, from about 0.2 g/cc to about 0.5 g/cc. As such, materials made from the nanotubes of the present invention can be substantially lighter in weight. In addition, carbon nanotubes of the present invention can exhibit a Seebeck coefficient that is substantially linear with temperatures, for example, from ambient to at least about 600° C.

It should be noted that although reference is made throughout the application to nanotubes synthesized from carbon, other compound(s), such as boron, MoS₂, or a combination thereof may be used in the synthesis of nanotubes in connection with the present invention. For instance, it should be understood that boron nanotubes may also be grown, but with different chemical precursors. In addition, it should be noted that boron may also be used to reduce resistivity in individual carbon nanotubes. Furthermore, other methods, such as plasma CVD or the like can also be used to fabricate the nanotubes of the present invention.

### Carbon Nanotube Sheets

Although sheets made from carbon nanotubes may be manufactured a similar manner to that described above, sheets of carbon nanotubes may also be made using other processes. For example, Buckey paper may be made by dispersing carbon nanotube “powder” in water with an appropriate surfactant to create a suspension. When this suspension is filtered through a membrane, a type of Buckey paper is created whose properties are illustrated in Table 1 below.

In one embodiment of the present invention, sheets of carbon nanotubes may be stretched to substantially align the carbon nanotubes within each sheet in order to improve properties of the nanotubes. The properties of a carbon nanotube sheet made in accordance with one embodiment of the present invention, and that of a Bucky paper are compared for illustrative purposes in Table 1 below.

TABLE I

| | | CNT Sheet of Present |
|---|---|---|
| Property | Bucky Paper | Invention |
| Tensile strength | 40 MPa | 800 to 1000 MPa |
| Modulus | 8 GPa | 20-100 GPa |
| Resistivity | 5 × 10 − 2 Ω-cm | <2 × 10⁻⁴ Ω-cm |
| Thermal conductivity | NA | 65 Watts/m-K |
| Seebeck Coefficient | NA | −60 μV/K n-type to |
| | | 70 μV/K p-type |
| | | (Be₂Te-287 μV/° |
| | | C. n-type) |
| Figure of Merit (400° C.) | NA | CNT~0.4 |
| ZT = S²*T*σ/TC | | (Bi₂Te₃~1) |
| ZT/ρ(g/cc) | | CNT~0.9 normalized |
| S(p/n) = 140 μV/K | | by density |
| σ = 10⁶ S/m | | Bi₂Te₃~0.13 normalized |
| TC = 20 W/mK | | by density |
| ΔT = 400 C. | | |

It should be note that, in Table 1, the figure of merit does not contain density or weight. However, since carbon nanotubes sheets can be substantially light, the resulting thermoelectric device or generator can nevertheless be designed with very high power to weight ratio.

It should be appreciated that the sheets from which the thermoelectric device may be made can include, in an embodiment, graphite of any type, for example, such as that from pyrograph fibers. Moreover, the sheets from which the thermoelectric device can be made may include traditional particles or microparticles, such as mesoporous carbons, activated carbon, or metal powders, as well as nanoparticles, so long as the material can be electrically and/or thermally conductive.

### Doping

A strategy for reducing the resistivity, and therefore increasing the conductivity of the nanotube sheets or yarns of the present invention, includes introducing trace amounts of foreign atoms (i.e. doping) during the nanotube growth process. Such an approach, in an embodiment, can employ any known protocols available in the art, and can be incorporated into the growth process of the present invention, as disclosed in U.S. patent application Ser. No. 11/488,387 (incorporated herein by reference).

In an alternate embodiment, post-growth doping of a collected nanotube sheet or yarn can also be utilized to reduce the resistivity. Post-growth doping may be achieved by heating a sample of nanotubes in a N₂ environment to about 1500° C. for up to about 4 hours. In addition, placing the carbon nanotube material over a crucible of B₂O₃ at these temperatures will also allow for boron doping of the material, which can be done concurrently with N₂ to create BₓN_{y}C_{z} nanotubes.

Examples of foreign elements which have been shown to have an effect in reducing resistivity in individual nanotubes include but are not limited to boron, nitrogen, boron-nitrogen, ozone, potassium and other alkali metals, and bromine.

In one embodiment, potassium-doped nanotubes have about an order of magnitude reduction in resistivity over pristine undoped nanotubes. Boron doping may also alter characteristics of the nanotubes. For example, boron doping can introduce p-type behavior into the inherently n-type nanotube. In particular, boron-mediated growth using BF₃/MeOH as the boron source has been observed to have an important effect on the electronic properties of the nanotubes. Other potential sources useful for boron doping of nanotubes include, but are not limited to B(OCH₃)₃, B₂H₆, and BCl₃.

Another source of dopants for use in connection with an embodiment of the present invention is nitrogen. Nitrogen doping may be done by adding melamine, acetonitrile, benzylamine, or dimethylformamide to the catalyst or carbon source. Carrying out carbon nanotube synthesis in a nitrogen atmosphere can also lead to small amounts of N-doping.

It should be appreciated that when doping the yarn or sheet made from nanotubes with a p-type dopant, such as boron, the Seebeck value and other electrical properties may remain p-type in a vacuum. On the other hand, by doping the yarn or sheet with a strong n-type dopant, such as nitrogen, the nanotubes can exhibit a negative Seebeck value, as well as other n-type electrical characteristics even under ambient conditions.

The resulting doped yarn or sheet of nanotubes can be used as a p-type element or an n-type element in the manufacture of a thermoelectric device or generator of the present invention.

### Thermoelectric Effect

Thermoelectric effect can generally be characterized to as a voltage difference that exists between two places on a conductor exhibiting a temperature difference. This effect, commonly referred to as the Seebeck effect, is defined as that voltage difference between two points when the temperature difference is 1° K.

To generate power efficiently, the conductor typically needs to have substantially good electrical conductivity, while having poor thermal conductivity. A figure of merit commonly known as Z is defined as:

### (1) Z=(Seebeck Coefficient)*Electrical Conductivity÷ Thermal Conductivity or

(2)Z=S²*ε/σ. This relationship comes from the consideration of useful power per degree divided by conducted power as shown below.
From the definition of S, the voltage across two points is:

### (3) V=S*ΔT

And the current through the conductor would be:

### (4) I=V/R=S*ΔT/R,

The power generated, not including convection or radiation losses, can be:
(5) Useful Power=I*V=S*ΔT*S*ΔT/(L/ρ*A)=(S*ΔT)²*ρ*A/L≈Constant, where L is the length of the thermoelectric element and A is the cross sectional area and ρ is the resistivity.
(6) The Thermal Power lost down the conductor is given by: Pₗₒₛₛ=σ*A*ΔT/L, where σ is the thermal conductivity.
(7) The ratio of electrical power generated to thermal power lost is the figure of merit, ZT: Ratio=(S*ΔT)²*ρ*A/L/σ*A*ΔT/L=S²ΔTρ/σ=Z*T

### Convection and Radiation

Heat loss from the conductor can impact energy generation. In particular, the lower the heat loss, due to radiation and/or convection, the higher the ΔT and so power of the device can be. Since both radiation losses and convection losses can be proportional to surface area to volume, the desired geometry for a thermoelectric generator may be that of a cylinder (i.e., yarn of nanotube) of short length. However, if the length is too short, then transmission losses can be high, as will be discussed below. As such, the figure of merit should include these types of losses.

### Efficiency

Typically, a ZT value of 1 can indicate that the thermoelectric device is about 50% efficient. A ZT value of 0.1, on the other hand, indicates an efficiency of about 10%. In general, the larger the ZT, the more efficient the device.

Looking at FIG. 1, the relationship between the Seebeck coefficient and a function of ZT is illustrated. In one example, for an n/p junction, the Seebeck coefficient for a thermoelectric device made from carbon nanotubes of the present invention can be about 140 μV/°K. It should be noted that although weight can be important, weight is not a consideration in FIG. 1.

### Specific Power

As noted above, traditional theremoelectric device made with Bi₂Te₃ has a density ranging from about 7.4 g/cc to about 7.7 g/cc, and may reach over 8 g/cc. The thermoelectric device made from nanotubes of the present invention, on the other hand, has a density range of from about 0.1 g/cc to about 1.0 g/cc, and more particularly, from about 0.2 g/cc to about 0.5 g/cc. As such, there can a factor of about 40 and up to about 80 in weight advantage for the carbon nanotubes of the present invention over Bi₂Te₃.

In addition, the Seebeck coefficient for a sheet of, for instance, substantially aligned carbon nanotubes may be from about −130 μV/°K to about −140 μV/°K in a combined p-type and n-type element. As such, a maximum voltage at a ΔT of 200° C., for example, can be about:

ΔV=ΔT*S=200×130×10⁻⁶=26 mV

Moreover, in addition to the high Seebeck effect and a substantially lower density in comparison to traditional material used in thermoelectric devices, the carbon nanotubes of the present invention can also have substantially lower thermal conductivity due to the existence of dual or multiwall nanotubes, or due to the aggregation of the nanotubes into large bundles. As such, the thermoelectric device made with nanotubes of the present invention can achieve relatively high specific power, for instance, greater than about 1000 W/kg and can exceed about 3000 W/kg at a ΔT of about 400° C.

This specific power compares well with that achieved for single junction solar cell based arrays, which may range from about 25 W/kg to about 100 W/kg, as well as the specific power for future multi-junction GaAs arrays, which may range from about 200 W/kg to about 1000 W/kg.

It should be appreciated that the Seebeck coefficient can exhibit an almost constant curve relative to temperature above 200° K. Such a property can suggest that at relatively high temperatures, for example, at about 600° C. or higher, the thermoelectric device made from nanotubes of the present invention can likely outperform those made with the more traditional semiconductor materials, such as Bi₂Te₃, since these traditional semiconductor materials can melt at about 556° C.

For most semiconductors, the ZT may vary considerably over a very short temperature interval. However, values of around 1 may be typical. Of the wide variety of semiconductors available, Bi₂Te₃ is often the most employed because of its relatively high ZT. Table II compares the specific ZT for Bi₂Te₃ with that for carbon nanotubes of the present invention.

TABLE II

| Parameter | CNT | CNT/density | Bi₂Te₃ | Bi₂Te₃/density |
|---|---|---|---|---|
| Z (μV/° K) | 70p, 70n or | NA | 54 | NA |
| | 140 for the | | | |
| | element | | | |
| ZT @ 300 C. | 0.4 | ~1 | 1 | ~0.13 |

As illustrated in FIG. 4, carbon nanotubes can exhibit a Seebeck coefficient that increases at low temperature but can be flat with temperature higher than about 200° C. The Seebeck coefficient is shown for individual nanotubes as a function of temperature up to near ambient temperature. This measured effect uses a relatively small change in temperature in a specimen in which the overall temperature can vary considerably. Such an approach differs from tests in which only the maximum temperature difference is plotted. It should be appreciated that data currently exist in the public domain only for individual tubes, ropes or bundles of tubes and composites, and only within a limited temperature range. Data on yarns and sheets, on the other hand, are reported herein for the first time.

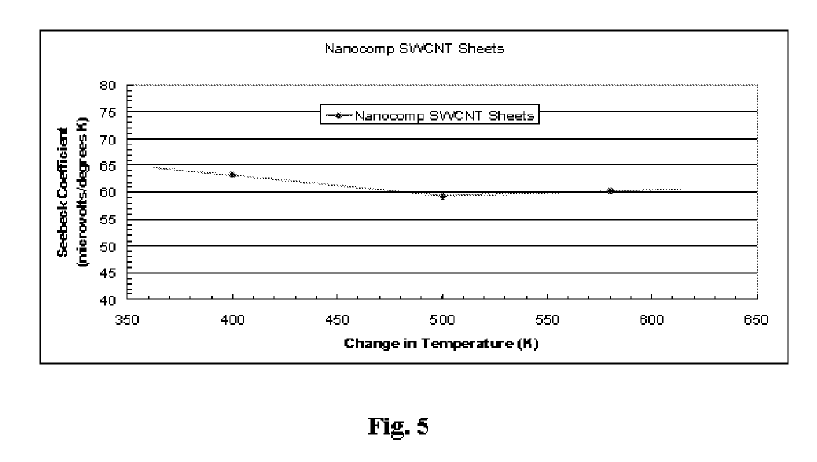

It has been observed and noted above that sheets made from substantially aligned single wall carbon nanotubes can exhibit a substantially high Seebeck coefficient, for example, on a same order as individual tubes or bundles. Measurements have been obtained ranging from about 325° K to about 600° K. These measurements are shown in FIG. 5. The Seebeck coefficients measured are with respect to copper contacts and are generally larger than about 60 μV/° K. These values may be marginally higher than for individual tubes, as shown in FIG. 4.

Some of the key thermoelectric parameters for a carbon nanotube material of the present invention in comparison to a semiconductor (Bi₂Te₃) material are listed in Table III.

TABLE III

| Parameter | Bi₂Te₃ | Carbon Nanotube Sheet |
|---|---|---|
| Seebeck Coefficient | 14 μV/° K at 300 K | >60 μV/° K (300° K to |
| | 50.4 μV/K at 644 K** | 700° K) |
| Power Factor | 4 × 10⁻³ W/k2 − m | 1.68 × 10⁻³ W/k2 − m |
| S²σ | | |
| Figure of Merit (ZT) | 0.8 to 1 | 0.4 |
| Measured | NA | 3 Watts/gram |
| Thermoelectric | | |
| Power/gram | | |

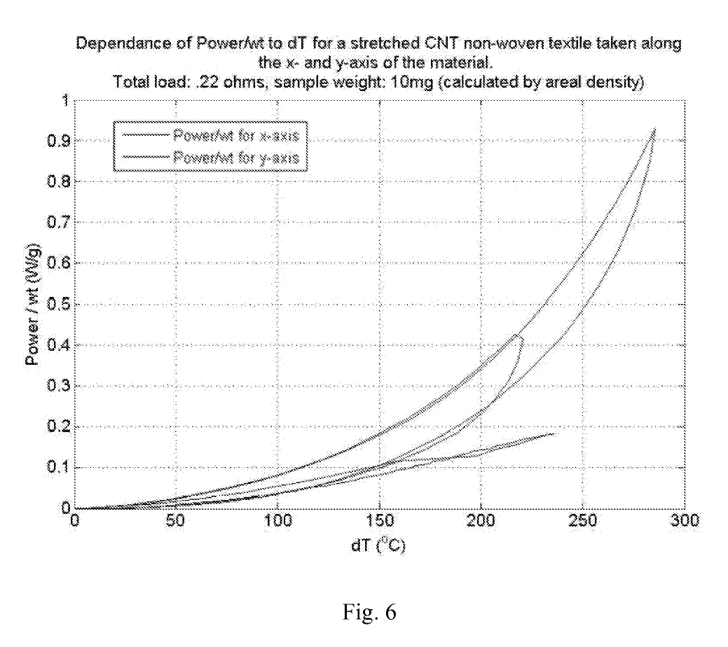

The power output from a thermoelectric device made from a sheet of single-walled carbon nanotubes in contact with a high conductivity metal, such as copper, is shown in FIG. 6. Note that for this device, the power is about 1 W/g. Other specimens, as noted above, have shown up to 3 Watts per gram at a ΔT of 400° C. As a note, a single stage element at ΔT of 400° K provides only 26 mV (65×10⁻⁶*400). These specific power can likely be higher as the temperature increases above 400° C.

Even though the specific power can be relatively high, the practical usable voltage can be low thereby requiring multiple stages or elements or an electronic device that transforms current to voltage.

### EXAMPLE I

In this example, a thermoelectric device or generator is provided using at least one carbon nanotube sheet made in accordance with an embodiment of the present invention.

With reference now to FIG. 7, there is shown a schematic diagram of an array 70 of a thermal element 71 and a conducting element 72 in substantial linear alignment. In one embodiment, element 71 can be a sheet of carbon nanotubes doped with a p-type dopant. Alternatively, element 71 can be a sheet of carbon nanotubes doped with an n-type dopant. Although reference is made to a sheet of carbon nanotubes, it should be appreciated that a plurality of sheets can be used, with each placed on top of one another. This is because, when using a plurality of sheets, the mass can increase, which can result in more power output in the thermoelectric device.

Conducting element 72, on the other hand, may be made from a metallic material, such as copper, nickel, or other similar conductive materials. In one embodiment, the conductive element 72 may be coated (e.g., electroplated) on to the thermal element 71 and subsequently laser cut to provide the segmented pattern as shown. The process of coating and laser etching can be similar to those processes known in the art.

Alternatively, rather than using a metallic material, a glassy carbon material may be used instead as the conducting element 72. In such an embodiment, lines of a glassy carbon precursor may be printed or placed on to the thermal element 71. The thermal element 71 with the glassy carbon precursor material may then be polymerized, in accordance with methods known in the art, to provide a glassy carbon material thereon. This embodiment can act to eliminate contact resistance and enable relatively higher operation temperatures.

To the extent that array 70 requires some stiffness, a high temperature polymer material, such as Torlon, or a polyamide material, may be affixed to the thermal element 71 and conductive element 72. The high temperature polymer or polyamide material, in an embodiment, can be substantially thin and can have a thickness ranging from about, 0.001″ to 0.005″. To affix the polymer or polyamide material to the thermal element 71 and conductive element 72, a thin film of glassy carbon resin, for instance, malic acid catalyzed furfuryl alcohol may be used to coat the polymer or polyamide material, followed by placement of the array 70 thereonto, then curing.

In an alternate embodiment, stiffness may be provided by initially coating one side of a high temperature polymer or polyamide material with copper, nickel or other similar materials to provide the conductive element 72. Next, the coated polymer or polyamide material can be photoprocessed. The polymer or polyamide material, thereafter, can be coated with a thin film of a glassy carbon resin, such as malic acid catalyzed furfuryl alcohol. A sheet or a stack of sheets of substantially aligned carbon nanotubes can then be affixed onto the polymer or polyamide material to provide thermal element 71. After curing, the resulting assembly can be laser cut to form linear array 70 of thermal element 71 and conductive element 72 illustrated in FIG. 7.

Voltage for linear array 70 can be calculated from V=n*50×10⁻⁶*ΔT. In one example, if n=100, and ΔT=250° C., then V=1.25 volts.

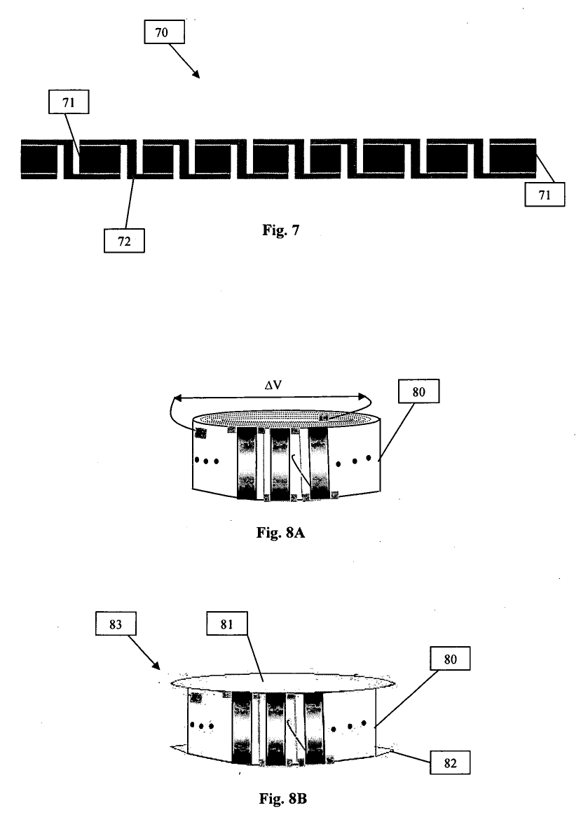

The linear array 70, formed by any of the above embodiments, can then be rolled up about an axis into a disk or core 80 as shown in FIG. 8A. It should be appreciated that in the embodiment where a polymer or polyamide material is not used, when forming core 80, the overlapping layers of the wrapped core 80 can be separated by the higher temperature polymer or polyamide material acting as an insulator, if so desired.

Once formed, the core 80 shown in FIG. 8B can be positioned between a thermal plate 81 attached to a one surface of core 80 and a thermal plate 82 attached to an opposing surface of core 80. It should be noted that one of the plates can act as a hot surface for collecting heat energy, while the other plate may act as a cool surface for dissipating heat energy from the hot surface. Thereafter, electrical connections can be made to form a thermoelectric device 83 or generator of the present invention. With such a design, heat collected by, for example, the thermal plate 81 on the top surface can be driven across the core 80 to the thermal plate 82 on the bottom surface due to a temperature differential between the two thermal plates. During the course of heat transfer, the design of core 80 allows it to convert the heat transferred across it into power.

With the ability to convert heat into power, the thermoelectric device 84 can act as a module that can be used for a wide variety of applications. It should be appreciated that this thermoelectric device is defined by a large cross-sectional area and small hot-cold gap spacing. Such a layout provides a substantially high current with the potential for dense packaging, while utilizing a light weight supporting structure. Moreover, the thermal conductivity through the carbon nanotube sheet can also be substantially high, meaning that for applications with limited thermal power input (e.g., solar collection, waste heat collection, etc.) the efficiency and power can be low. However, with unlimited thermal power, the power to weight ratio can exceed 3 W/g.

In one embodiment, the voltage of device 84 can be characterized by:

V=n*26 mV.

Thus, for example, if V=1.4 V and ΔT=200° C. then n=54, if ΔT=400° C., then n=75 per device.

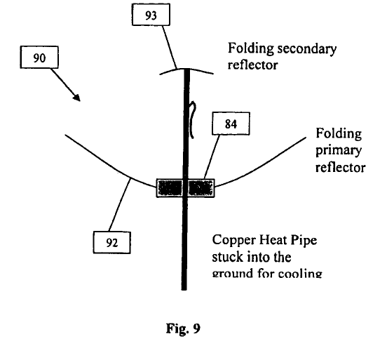

One application for the thermoelectric generator or device 84 is to use it in connection with a small sun collector 90, as shown in FIG. 9. This solar collector 90, as illustrated, includes thermoelectric device 84 placed at the secondary focus of the collector 90. Sun collector 90 can also include reflectors 92 and 93, both of which may be designed to fold out. In an embodiment, reflector 92 may have a 1 inch radius when unfolded, and the entire set up of sun collector 90 may be the size of a pencil. With such a size, sun collector 90 may be used for battery charging applications on one scale with an estimated solar conversion efficiency of at least about 10-15%. Such a conversion efficiency by the sun collector 90 compares favorably with a similar photocell type generator, despite being at a much lighter weight and at lower cost.

In another embodiment, the collector 90 can be designed to produce a few 10's or 100's of mW for battery charging. Larger configurations, of course, can be designed when more power is desired.

Another application for the thermoelectric device 84 or generator shown in FIG. 8B can be used as a large area power generator for houses, buildings, cities etc. For instance, the use of heliostats (or simple concave mirrors) allows the concentration of a significant amount of solar energy into a small area, where a hot end of a thermoelectric generator can absorb the solar energy. In addition, the use of thermoelectric device 84 can allow for relatively high conversion efficiencies of heat to electrical work with no moving parts. Moreover, since the thermoelectric device 84 includes elements 71 and 72 with substantially high chemical stability, device 84 can be durable and can last over a long period.

The thermoelectric device 84 may also be used as a heat or energy engine. In one embodiment, the thermoelectric device 84 can be used as an energy generator from waste heat. In particular, device 84 may be attached so that its hot surface contact a source of waste heat, such as a pipe in a heating system, while its cool surface contact a cold sink, so that heat can be transferred thereto and heat up the cold sink area, and cool down the heat source area. In accordance with one embodiment, if a 1 kg of nonwoven nanotube sheets of the present invention is used to manufacture device 84 for use as a heat or energy engine, such a heat or energy engine can directly convert heat to electrical work, and can put out approximately 1 kW of power. Such a capability allows for a lightweight replacement of, for instance, car and truck alternators, as well as power supplies for marine & aerospace applications. Large scale systems containing a metric ton of nanotubes of the present invention can put out in principle, a megawatt.

The design of such a heat or energy engine can also be used to cool down, for instance a submarine. In particular, the thermoelectric element may be attached to the hot reactor tube of a nuclear submarine on one side, and on the other side to the cold hull of the submarine adjacent to cold ocean water to permit the reactor tube to cool down.

A similar design can be used to incorporate into clothing to transfer heat from the body, which acts as the heat source, to cooler environment, such as air, to cool down the wearer.

### EXAMPLE II

In this embodiment, a thermoelectric device is provided using at least one carbon nanotube yarn made in accordance with an embodiment of the present invention.

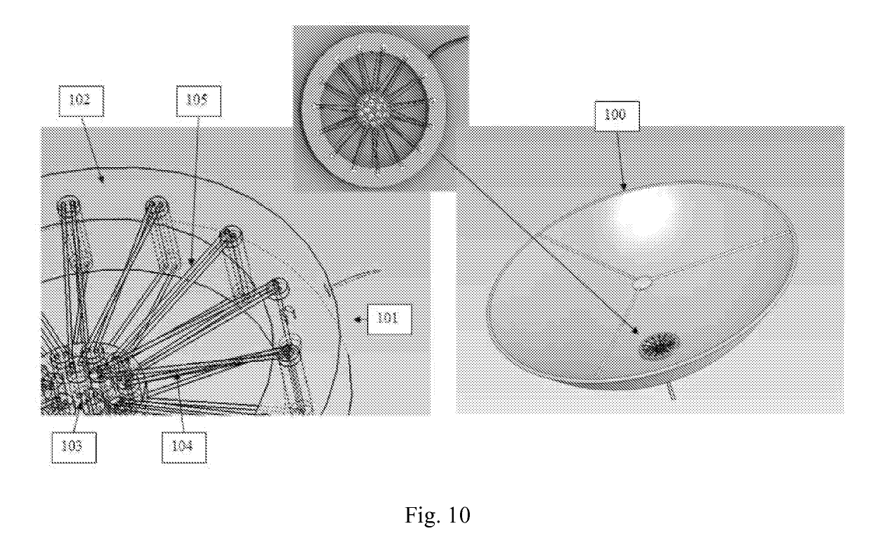

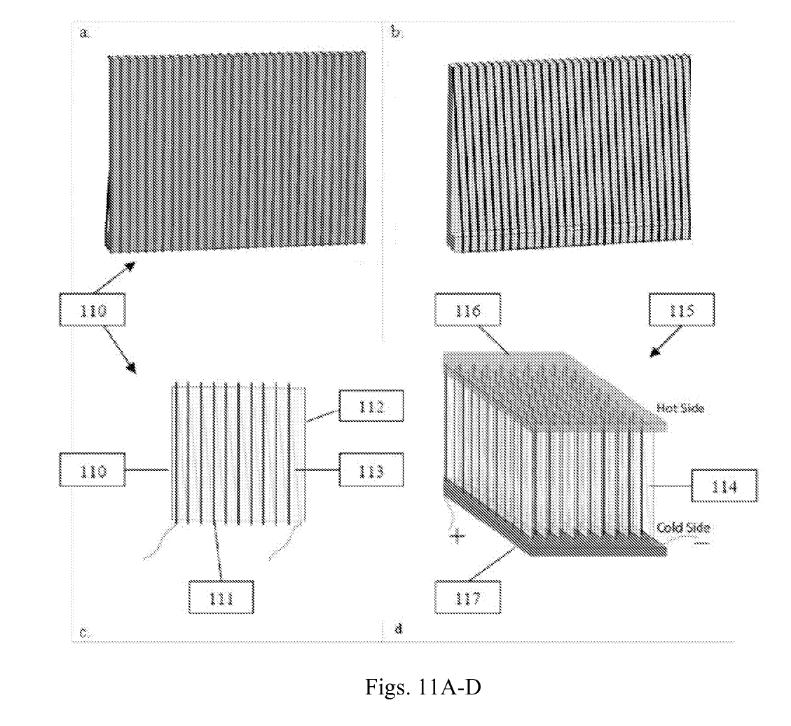

Looking now at FIG. 10, a solar collector 100 is provided. The solar collector 100, in an embodiment, includes a thermoelectric device 101 having a outer ring 102 and an inner member 103 concentrically positioned relative to the outer ring 102. Inner member 103, as illustrated, may be a hot plate designed to collect heat from solar rays, while outer ring 102 may be a cool plate designed to dissipate heat. Thermoelectric device 101 may also include a core 104 having at least one carbon nanotube yarn 105, made from a plurality of intertwined nanotubes in substantially alignment. Yarn 105, in an embodiment, extends radially between the inner member 103 and the outer ring 102, and can act as a thermal element. In one embodiment, yarn 105 may be a p-type element or n-type element coated (i.e., electroplated) along its length with a segmented pattern of a metallic material, such as copper or nickel, so that between consecutive coated segments is a segment of non-coated nanotube yarn. The coated segments of yarn 105, in an embodiment, can act as a conductive element, while the non-coated segments of yarn 105 can act as a thermal element. As illustrated, the end of yarn 105 in contact with the hot plate inner member 103 can act as a negative lead, while the opposite end of yarn 105 in contact with the cool plate outer ring 102 can act as a positive lead. Because of its design, the long thin yarn 105 (i.e., thermal element) can be defined by a high gap length and a small cross-sectional area. Such a design, in an embodiment, can allow the solar collector 100 to maximize the difference in temperature between a hot inner member 103 and the cool outer ring 102 by minimizing heat transfer from inner member 103 to outer ring 102. Moreover, since there may be no conducting media, other than the carbon nanotubes yarn 105, the design of solar collector 100 makes it substantially efficient in terms of minimizing waste heat transfer.

### EXAMPLE III

In this embodiment, a multi-element thermoelectric array is provided using a plurality of carbon nanotube yarns made in accordance with one embodiment of the present invention.

As illustrated in FIGS. 11A-D, a thin thermoelectric panel 110 is provided. The thin panel 110, in an embodiment, includes a plurality of thin thermal elements 111 (FIG. 11C) made from nanotube yarns. In one embodiment, about 30-1000 or more elements 111 having high hot-cold gap length and a small cross-section can be provided on the thin panel 110. These elements 111, designed to act as p-type elements, may be positioned on, for example, a substrate 112 made from, for example, aluminum nitride, mica or other similar material. In an embodiment, the substrate 112 may be coated with copper or nickel on a side on which the carbon nanotube thermal elements are situated (FIG. 11A), while its opposite side remains uncoated (FIG. 11B). On the uncoated side, panel 110 may be provided with a plurality of copper wires 113 acting as n-type elements. In one embodiment, each copper wire 113 may be connected to a corresponding thermal element 111, as shown in FIG. 11C. To the extent desired, a plurality of thin panels 110 may be assembled into a core 114 of for use as a thermoelectric device 115, as illustrated in FIG. 11D. Such a device 115 includes a first plate 116 acting as a hot surface, and a second plate 117 acting as a cool surface. Plates 116 and 117, in an embodiment, may be made from heat conducting materials, such as alumina. With such a design, heat collected by the first plate 116 can be driven across the core 114 to the second plate 117 due to a temperature differential between the first plate 116 and the second plate 117. During the course of heat transfer, the design of core 114 allows it to convert the heat transferred across it into power.

Although shown with a plurality of panels 110, it should be noted that device 115 can include just one panel 110, and that the device 115, including the thermoelectric panel 110, can be used or designed to have any of a number of other configurations. In addition, nickel wires 113 may be used in place of copper wires 113, or n-type nanotube yarns can be used in place of wires 113.

This design of panel 110 can be mechanically robust. In an embodiment, in order to obtain, for instance, 1.5 volts at about a ΔT of 400° K, the number of thermal elements 111 utilized within panel 110 may be about 58. Moreover, in a vacuum, the panel 110 has the potential for a wide range of operating temperatures, from the highest to perhaps the lowest of operating temperatures. In addition, the highly dense array of thermal elements 111 can give the panel 110 a substantially high operating voltage per unit of heated area in comparison to any of the designs provided above. In an embodiment, if spacing of thermal elements 111 is too close, then cold junctions in panel 110 may need to be heated to raise the temperature.

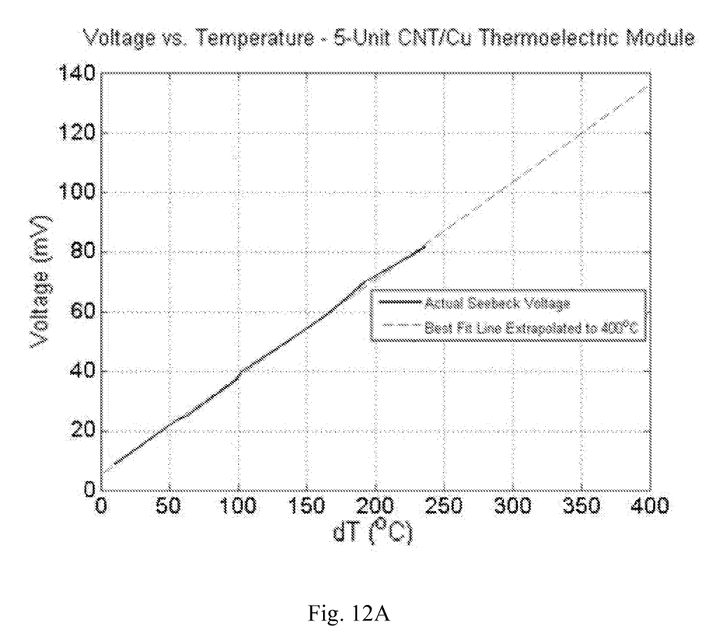

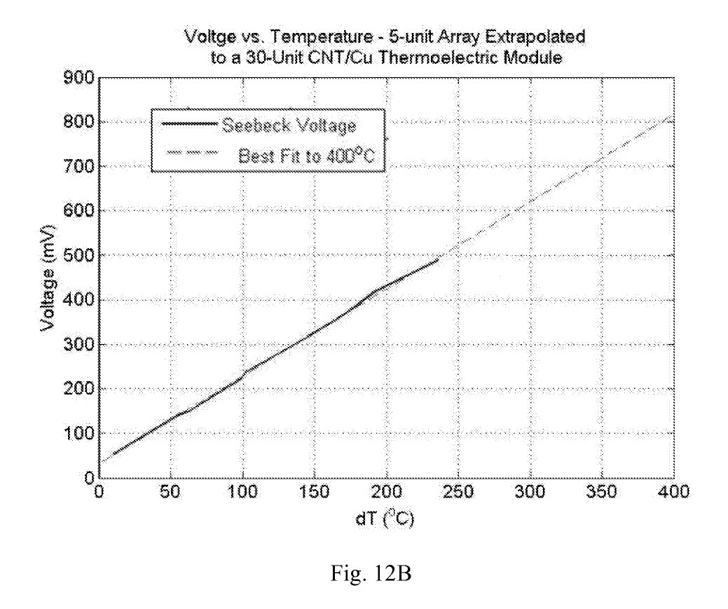

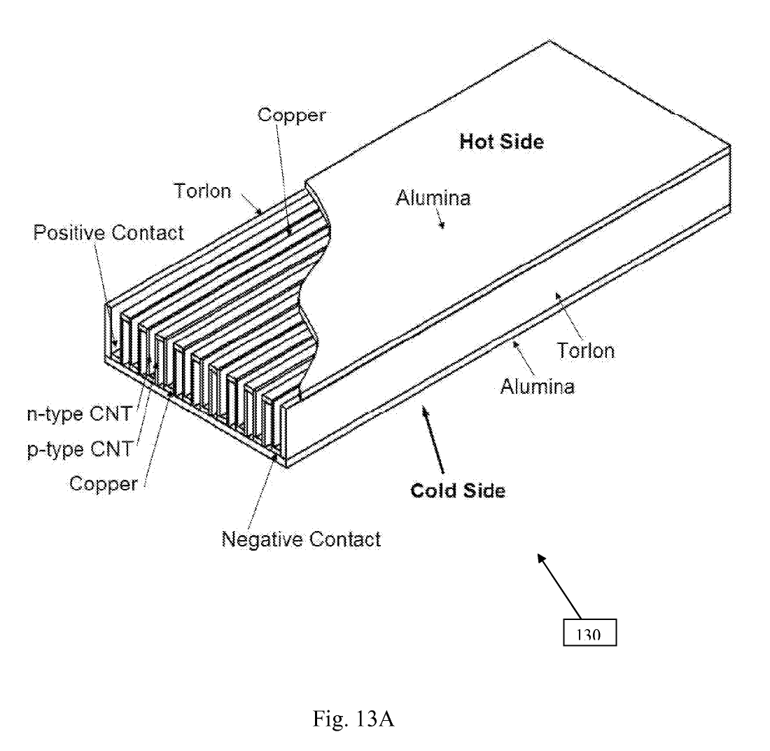

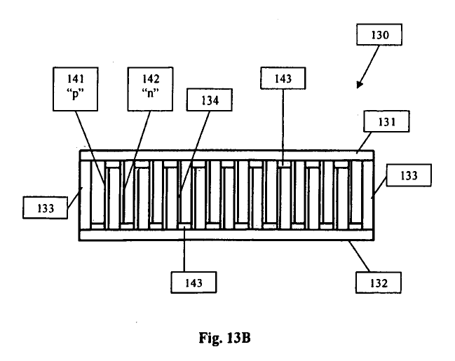

FIGS. 12A-B illustrate data obtained from a panel having an array of thermal elements 111. In particular, data from a 5 element panel and from a 30 element panel are illustrated in FIG. 12A and FIG. 12B respectively. These panels, similar to panel 110 above, includes a coated side having p-type carbon nanotube thermal elements, and an uncoated side having copper or nickel n-type elements. In an embodiment, these panels may be about 1 cm by 1 cm in size. Alternatively, the copper or nickel n-type elements can be substituted with n-type nanotube yarns. Note the y-axis scale differences between the two arrays.

### EXAMPLE IV

In space applications, a geometry, such as that shown in FIGS. 11A-D may be able to handle substantially high power. In particular, in space, radiation can be used for cooling. For example, placing an insulated reflector on the back side of the substrate 112 and suspending the carbon nanotube yarns (i.e., elements 111) above this reflector can be used for high heat transfer. Further, in accordance with an embodiment, by heating p-type nanotubes in vacuum, it is possible to reversibly transformed p-type nanotubes to n-type. In other words, exposing the p-type nanotubes to a vacuum environment at an elevated temperature can transform such nanotubes to n-type. On the other hand, doping the p-type nanotubes can permanently stabilize them. Accordingly, by making device 115, as shown in FIG. 11D, from a single yarn and appropriately masking it during the doping operation, a substantially high Seebeck coefficient array can be made that is capable of generating high power for space applications.

This geometry can also be modified by introducing a reflector on the back surface and doping the nanotubes after growth with boron using a selective masking technique.

### EXAMPLE V

Waste heat is essentially a free, readily-available source of energy which can be converted into useful forms through an energy harvesting device of the present invention.

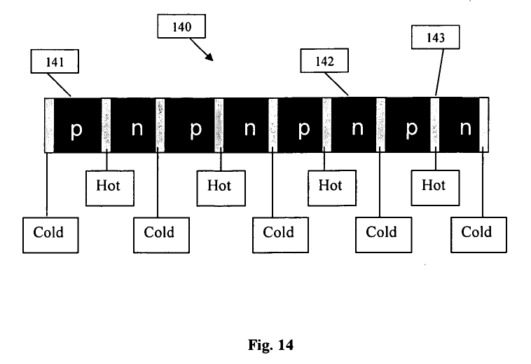

FIGS. 13A-B illustrates one possible configuration of a thermoelectric device 130 useful for energy harvesting. Device 130, as shown, includes a top plate 131 and a bottom plate 132, both of which may be made from, in an embodiment, heat-conducting alumina, such as aluminum nitride. In one embodiment, top plate 131, for instance, can act as a hot surface for collecting heat energy, while the bottom plate 132 can act as a cool surface for dissipating heat energy from the top plate 131. Thermoelectric device 130 also includes supports 133 situated between top plate 131 and bottom plate 132. Supports 133, in one embodiment, may be made from a low-thermal-conductivity material, such as Torlon. Device 130 further includes a core 134 situated between supports 133 and extending from the top plate 131 to the bottom plate 132. In an embodiment, core 134 may be provided with a design such as that illustrated in FIG. 14. Specifically, core 134 may include a nanotube sheet having one segment doped with a p-type dopant and an adjacent segment doped with an n-type dopant, in an alternating pattern to provide a linear array 140 of alternating p-type elements 141 and n-type elements 142. Moreover, as illustrated, between adjacent p-type element 141 and n-type element 142, a conducting element 143 can be provided to join the p-type element 141 with the n-type element 142. Furthermore, one end of linear array 140 can be designed to act as a positive contact, while the opposite end can act as a negative contact (See FIG. 13A).

With particular reference now to FIG. 13B, in the embodiment shown, the core 134 can include a series of nine alternating “n” and “p” type thermal elements 141 and 142 made from a carbon nanotube sheet. The nanotube sheet, in one embodiment, can be folded accordion style and placed between the supports 133, such that every other conducting element 143 is in contact with the hot top plate 131, while each of the remaining adjacent conducting elements 143 is in contact with the cool bottom plate 132.

Although shown with nine alternating “n” and “p” type elements, it should be appreciated that, if desired, core 134 can be made to have more than or less than the nine alternating “n” and “p” type elements shown. Moreover, rather than just one nanotube sheet, a plurality of nanotube sheets having alternating “n” and “p” type elements may be used. When utilizing a plurality of nanotube sheets, each sheet may be placed on top of one another, or each sheet placed adjacent to and in parallel to one another, or both. Regardless of the arrangement of the sheets, when using a plurality of sheets, the mass of core 134 can increase, which can result in more power output in the thermoelectric device 130.

To provide the doped pattern in array 140, in one embodiment, the n-type elements 142 may be doped (i.e., chemically treated) with chemicals or chemical solutions that can act as electron donors when adsorbed onto the surface of the nanotubes, making the resulting n-type elements 142 electron-doped. Examples of such chemicals or chemical solutions include polyethylenimine (PEI) and hydrazine. Other chemicals or chemical solutions can also be used. Of course, traditional doping protocols may instead be used.

Table IV illustrates solutions used and their effect on carbon nanotube materials.

TABLE IV

| | | | | | Seebeck |
|---|---|---|---|---|---|
| | | | | | after |
| | | Starting | Ending | | Secondary |
| | | Seebeck | Seebeck | Secondary | Treatment |
| Sample # | Treatment | (uV/K) | (uV/K) | Treatment | (uV/K) |
| 1 | Polyethylenimine (PEI, | 32 | −58 | Bake 2 hr @ | 75 |
| | H(NHCH₂CH₂)nNH₂) 20 wt % in | | | 250 C. | |
| | EtOH | | | | |
| 3a | Tri-octyl phosphene (TOP, | 32 | −14 | | |
| | [CH₃(CH₂)₇]₃P) 20 wt % in EtOH | | | | |
| 3b | Tri-octyl phosphene (TOP) 20 wt % | 32 | −62 | Bake 2 hr @ | 70 |
| | in Hexane | | | 325 C. | |
| 3c | 100% TOP | 32 | −61 | | |
| 4a | Tri-phenyl phosphine 20 wt % in | 32 | −15 | | |
| | acetone | | | | |
| 5 | Hydrazine, NH₂NH₂ | | | | |
| 6 | Ammonia, NH₃ | | | | |
| 7 | Aniline, C₆H₅NH₂ | | | | |
| 8 | Sodium Azide, NaN₃ | | | | |
| 9 | Melamine, C₃H₆N₆ | | | | |
| 10 | Acetonitrile, CH₃CN | | | | |
| 11 | Benzylaime, C₆H₅CH₂NH₂ | | | | |
| 12 | Polyvinylpyrrolidone ((PVP, | | | | |
| | (C₆H₉NO)ₙ) | | | | |
| 13 | N-Methylpyrrolidone (NMP, | | | | |
| | C₅H₉NO) | | | | |
| 14 | Polyaniline | | | | |
| 15 | Amino butyl phosphonic acid | | | | |

In one embodiment, treatment of n-type elements 142 can be as follows. Strips of copper 143 are electroplated onto the a carbon nanotube sheet to divide it into distinct sections. Every other section, in an embodiment, can be doped to n-type 142, as shown in FIG. 14. The sections to be n-type are then treated with a concentrated electron-rich solution of one of the chemicals listed in Table IV. After the n-type sections are carefully rinsed, the strip is folded, accordion-style and soldered between the two alumina plates 131 and 132. The Seebeck coefficient produced from the “n” and “p” type sections is, respectively, −60 μV/° K and 70 μV/° K, which gives a total of 130 V/° K per element.

This device can also be used as a Peltier device, using the flow of electrons or holes within the thermoelectric material to pump heat from one side of the device to the other. The internal thermoelectric element can be modified slightly from the energy harvesting version to increase the efficiency. The treatment remains the same as above with the exception that a multi-layered piece of nanotube material may be used (thickness of about 1-2 mm) with the nanotube materials placed on top of one another. Short, square elements can then be cut from the treated nanotube material and soldered between the alumina plates, thus increasing the contact area between the thermoelectric material and the alumina.

### Advantages

Advantages of the thermal and conductive elements used in thermoelectric device of the present invention include:

High semiconductor transition temperature of up to 600° C.

High power output of greater than 1 W/g to 3 W/g at a 400° C. difference in temperature.

Substantially light in weight and low cost when compared with the commercially available semiconductor material in large volumes.

Voltages can be tailored by increasing the number of elements in an array.

### Applications

The thermoelectric device or generator of the present can be utilized for a number of other applications. Among these, devices can be manufactured for applications including: (1) A solar battery charger (2) A high energy light weight transient thermal battery replacement placed in rockets or missiles, (3) A low temperature energy harvester suitable for body heat battery charging or applications used at very low temperatures, such as sub-zero (i.e., below 0° C.) or temperatures in space or in Arctic or Antarctic environments, and (4) a 1 Mega-Watt thermal generator.

Light weight thermoelectric devices can also be manufactured in combination with solar cells to capture the waste heat radiated to space. These devices can be designed to operate at a temperature of about 370° K and radiate to about a 50° K background. This very large ΔT should enable the capture of significant amounts of now wasted power and allow the solar arrays to operate at a reduced temperature thereby improving their efficiency.

Carbon nanotube thermoelectric devices of the present invention can further be used in conjunction with waste heat from satellites, communication electronics, and power systems, for power harvesting and thermal management purposes. An example may be a body heat powered device used for charging batteries. In particular, carbon nanotube thermoelectric blanket power sources could replace delicate, heavy, and expensive GaAs cell and coated cover glass components in photovoltaic arrays, so as to eliminate the costly multi-step assembly. This in turn would permit improved on-station altitude control and reduced propellant usage for either lower launch costs or extended mission operations. Future civil and defense spacecraft may also need more efficient, higher power sources and improved thermal management systems in order to meet escalating mission performance goals. As such, the thermoelectric devices of the present invention can be used for such purposes

Another example may be to use the thermoelectric devices of the present invention in conjunction with various machines, electronic devices, power systems that generate waste heat. The present invention contemplates using the thermoelectric devices to harvest the waste heat, converting the waste heat to power, and redirecting the power to these machines, devices or systems for reused, so as to enhance efficiency and reduce overall power usage.

Moreover, whether used for megawatt-class space-based radar platforms, radio isotope thermoelectric generator (RTG) powered deep space exploration missions, or orbiting nanosat clusters, a high specific power technology such as that offered by the thermoelectric power generators can be a key enabler in each mission area and can provide a strong competitive advantage.

Ground-based devices can also be designed from the thermoelectric element of the present invention.

While the present invention has been described with reference to certain embodiments thereof, it should be understood by those skilled in the art that various changes may be made and equivalents may be substituted without departing from the true spirit and scope of the invention. In addition, many modifications may be made to adapt to a particular situation, indication, material and composition of matter, process step or steps, without departing from the spirit and scope of the present invention. All such modifications are intended to be within the scope of the claims appended hereto.

What is claimed:

1. A thermoelectric device comprising:
a first member designed to collect heat from a heat source;
a second member in spaced relations from the first member for dissipating heat from the first member; and
a core positioned between the first member and a second member for converting heat from the first member to useful energy, the core having a nanotube thermal element exhibiting a relatively high Seebeck coefficient that increases with an increase in temperature, and a conductive element exhibiting a relatively high transition temperature, the elements coupled to one another allowing the core to operate within a substantially high temperature range.

2. A device as set forth in claim 1, wherein the first member is designed to withstand temperatures ranging from below 0° C. up to about 600° C. and above.

3. A device as set forth in claim 1, wherein the first member and second member are made from aluminum nitride.

4. A device as set forth in claim 1, wherein the core is designed to withstand temperatures ranging from below 0° C. up to about 600° C. and above.

5. A device as set forth in claim 1, wherein the core is designed to achieve a relatively high specific power up to and exceeding about 3 W/g at a ΔT of about 400° C.

6. A device as set forth in claim 1, wherein the nanotube thermal element has a density range of from about 0.1 g/cc to about 1.0 g/cc.

7. A device as set forth in claim 1, wherein the nanotube thermal element exhibits relatively low thermal conductivity.

8. A device as set forth in claim 1, wherein the core comprises an array of the nanotube thermal element and conductive element in linear alignment, the array being wrapped about an axis to form a disk.

9. A device as set forth in claim 8, wherein the nanotube thermal element includes a sheet of carbon nanotubes doped with one of a p-type dopant or n-type dopant.

10. A device as set forth in claim 8, wherein the thermal element includes a plurality of carbon nanotube sheets, each being placed on top of the other, so as to increase the power being generated by the device.

11. A device as set forth in claim 8, wherein the conductive element includes one of copper, nickel, or other similar metallic materials.

12. A device as set forth in claim 8, wherein the conductive element includes a glassy carbon material.

13. A device as set forth in claim 8, further including a high temperature polymer or a polyamide material for use as a stiffener or insulator in the core.

14. A device as set forth in claim 1, wherein the core comprises a plurality of nanotube yarns extending between the first member and the second member, each yarn being coated along its length with a segmented pattern of a metallic material, so that between consecutive coated segments is a segment of non-coated nanotube yarn.

15. A device as set forth in claim 14, wherein each coated segment of the yarn acts as a conductive element, while each non-coated segment of the yarn acts as a thermal element.

16. A device as set forth in claim 14, wherein the coated segments includes one of copper, nickel, or other similar metallic materials.

17. A device as set forth in claim 14, wherein the non-coated segments is doped with one of a p-type dopant or n-type dopant.

18. A device as set forth in claim 14, wherein the plurality of nanotube yarns can act to minimize heat transfer from one member to the other member.

19. A device as set forth in claim 14, wherein the first and second member are circular and are concentrically positioned relative to one another.

20. A device as set forth in claim 1, wherein the core comprises at least one panel having a plurality of thermal elements on one side of the panel, and a plurality of conductive elements in contact with the thermal elements while being positioned on an opposite side of the panel.

21. A device as set forth in claim 20, wherein the panel includes a coating of a metallic material on the side having the thermal elements.

22. A device as set forth in claim 21, wherein the metallic coating includes one of copper, nickel, or other similar metallic materials.

23. A device as set forth in claim 20, wherein the panel is made from one of aluminum nitride, mica, or other similar materials.

24. A device as set forth in claim 20, wherein each thermal element is a nanotube yarn designed to act as a p-type element.

25. A device as set forth in claim 20, wherein each conductive element is a metallic wire acting as an n-type element.

26. A device as set forth in claim 25, wherein the wire is made from one of copper, nickel, or other similar metallic materials.

27. A device as set forth in claim 20, wherein the first and second member is made from alumina.

28. A device as set forth in claim 1, wherein the core includes an alternating array of the nanotube thermal elements and conductive elements in linear alignment.

29. A device as set forth in claim 28, wherein the core is provided with a configuration such that, when placed between the first member and the second member, every other conducting element is in contact with the first member, while each of the remaining adjacent conducting elements is in contact with second member.

30. A device as set forth in claim 28, wherein the thermal element includes a plurality of carbon nanotube sheets, each being placed on top of the other, so as to increase the power being generated by the device.

31. A device as set forth in claim 28, wherein the thermal elements include a sheet of carbon nanotubes having one segment doped with a p-type dopant and an adjacent segment doped with an n-type dopant in an alternating pattern.

32. A device as set forth in claim 31, wherein each conductive element is positioned between adjacent p-type and n-type segments on the sheet of carbon nanotubes.

33. A device as set forth in claim 28, wherein the conductive elements are made from one of copper, nickel, or other similar materials.

34. A device as set forth in claim 1 for use as an solar energy collector or harvester with a conversion efficiency of at least about 10-15 percent.

35. A device as set forth in claim 34 for use in battery charging applications.

36. A device as set forth in claim 34 for use as a large area power generator for one of houses, buildings, or cities.

37. A device as set forth in claim 1 for use as heat or energy engine to directly transform heat to electrical work.

38. A device as set forth in claim 37 for use as an energy generator from waste heat.

39. A device as set forth in claim 38 for use as a combustion engine for automobile, marine, aerospace or space applications.

40. A device as set forth in claim 1 for use as a low temperature energy harvester for sub-zero temperature applications.

41. A method of generating power, the method comprising:
providing a thermoelectric device having (i) a first member designed to collect heat from a heat source, (ii) a second member in spaced relations from the first member for dissipating heat from the first member, and (iii) a core positioned between the first member and a second member for converting heat from the first member to useful energy, the core having a nanotube thermal element exhibiting a relatively high Seebeck coefficient that increases with an increase in temperature, and a conductive element exhibiting a relatively high transition temperature, the elements coupled to one another allowing the core to operate in a substantially high temperature range;
positioning the device so as to permit the first member to collect heat from a heat source;
driving the collected heat across the core to the second member due to a temperature differential between the first member and the second member; and
allowing the core of the device to convert the heat being transferred across it to be converted to power.

42. A method as set forth in claim 41, further including directing the power generated to another device to permit that device to operate.

43. A method as set forth in claim 41, wherein the step of providing includes coupling the thermoelectric device to a machine or device capable of generating waste heat, so that the waste heat can act as a heat source to be captured and converted to power and redirected to the machine for further use.

44. A method as set forth in claim 41, wherein the step of providing includes increasing the number of thermal elements and conductive elements in the core to enhance efficiency and/or power generated.

45. A method as set forth in claim 41, wherein, in the step of providing, the nanotube thermal element has a density range of from about 0.1 g/cc to about 1.0 g/cc.

46. A method as set forth in claim 41, wherein, in the step of providing, the nanotube thermal element exhibits relatively low thermal conductivity.

47. A method as set forth in claim 41, wherein, in the step of positioning, the heat source can have a temperature ranging from below 0° C. up to about 600° C. and above.

48. A method as set forth in claim 41, wherein, in the step of allowing, the power generated can be up to and exceeding about 3 W/g at a ΔT of about 400° C.

49. A method of manufacturing a thermoelectric device, the method comprising:
providing at least one nanotube thermal element exhibiting a relatively high Seebeck coefficient that increases with an increase in temperature;
coupling the thermal element to a corresponding conductive element exhibiting a relatively high transition temperature to provide a core member; and
positioning the core member between a first member designed to collect heat from a heat source, and a second member in spaced relations from the first member for dissipating heat from the first member.

50. A method as set forth in claim 49, wherein, in the step of providing, the nanotube thermal element has a density range of from about 0.1 g/cc to about 1.0 g/cc.

51. A method as set forth in claim 49, wherein, in the step of providing, the nanotube thermal element exhibits relatively low thermal conductivity

52. A method as set forth in claim 49, wherein the step of providing includes doping the nanotube thermal element with one of a p-type dopant, n-type dopant, or both.

53. A method as set forth in claim 49, wherein the step of providing includes increasing the number of nanotube thermal elements within the core, and corresponding conductive element, so as to provide the device with the ability to increase the power generated.

54. A method as set forth in claim 49, wherein, in the step of coupling, the thermal element and the conductive element can withstand a temperature range of from below 0° C. up to about 600° C. and above.
